(19) United States
(12) Patent Application Publication
(10) Pub. No.: US 2012/0024353 A1
(43) Pub. Date: Feb. 2, 2012

(54) THERMOFORMABLE PHOTOVOLTAIC BACKSHEET

(75) Inventors: Jiaxin Jason Ge, Lover Providence, PA (US); Michael T. Burchill, Langhorne, PA (US); Ravi R. Gupta, Pottstown, PA (US); Steven B. Lacock, Boyertown, PA (US); Mark A. Aubart, West Chester, PA (US); Robert A. Wanat, Langhorne, PA (US)

(73) Assignee: Arkema France, Colombes (FR)

(21) Appl. No.: 13/254,101

(22) PCT Filed: Mar. 1, 2010
(86) PCT No.: PCT/US10/25732

§ 371 Date: Aug. 31, 2011

Related U.S. Application Data
(60) Provisional application No. 61/157,022, filed on Mar. 3, 2009.

(51) Int. Cl. H01L 31/048

(52) U.S. Cl. 136/251

(57) ABSTRACT

The invention relates to high Tg monolithic and multi-layer thermoformable film or sheet useful as a backsheet on a photovoltaic module (PV). A methacrylic-based material is preferred. The film or sheet is formed of a composition having a Tg greater than 110° C. The methacrylic composition may be a blend of a polymethyl methacrylate polymer and a miscible or semi-miscible high Tg polymer, or may be a copolymer containing primarily methyl methacrylate monomer units. The backsheet is optionally covered with a fluoropolymer or acrylic/fiuoropolymer covering on the outside (side facing the environment). The back-sheet can be clear, white, and/or pigmented. The film or sheet is especially useful in concentrating photovoltaic modules (CPV), and is also useful in thin film photovoltaic modules.

### FIELD OF THE INVENTION

The invention relates to high Tg monolithic and multi-layer thermoformable film or sheet useful as a backsheet on a photovoltaic module (PV). A methacrylic-based material is preferred. The film or sheet is formed of a composition having a Tg greater than 110° C. The methacrylic composition may be a blend of a polymethyl methacrylate polymer and a miscible or semi-miscible high Tg polymer, or may be a copolymer containing primarily methyl methacrylate monomer units. The backsheet is optionally covered with a fluoropolymer or acrylic/fluoropolymer covering on the outside (side facing the environment). The backsheet can be clear, white, and/or pigmented. The film or sheet is especially useful in concentrating photovoltaic modules (CPV), and is also useful in thin film photovoltaic modules.

### BACKGROUND OF THE INVENTION

Photovoltaic modules are made up of an outer glazing material, solar cells that are generally encapsulated in a clear packaging for protection, and a backsheet. The solar cells are made of materials known for use in solar collectors, including, but not limited to, silicon, cadmium indium selenide (CIS), cadmium indium gallium selenide (CIGS), and quantum dots. The back sheet is exposed to the environment on the backside of the photovoltaic module. The primary function of the back sheet is to provide low water vapor transmission, UV protection, and oxygen barrier properties necessary to protect the photocells (for example, silicon wafers) from degradation induced by reaction with water, oxygen and/or UV radiation. Because the photocells are generally encapsulated in ethylene vinyl acetate (EVA), or a thermoplastic encapsulant, the backsheet material should adhere well to EVA or the thermoplastic encapsulant when the components are laminated together in a thermoforming process.

The backsheet of the collector can be a metal sheet, such as steel or aluminum. However, more recently polymeric materials have been used. TEDLAR, a polyvinyl fluoride (PVF) material from DuPont (U.S. Pat. No. 6,646,196), an ionomer/nylon alloy (U.S. Pat. No. 6,660,930), and polyethylene terephthalate (PET) have all been used as the backsheet layer in photovoltaic modules, alone and in combination. PET exhibits excellent water vapor resistance at a relatively low cost; however, it is susceptible to degradation from exposure to environmental influences, such as UV and IR radiation, and ozone. In many backsheet constructions, PET is protected by PVF films, which are tough, photo-stable, chemically resistant, and unaffected by long-term moisture exposure. They also adhere well to EVA after surface treatments. PVF films are relatively expensive, and exhibit good resistance to water vapor. Thus the combination of PVF film and PET can act as an excellent backsheet material. Typical constructions of photovoltaic back sheets are PVF/PET/PVF, PVF/Al/PVF and PVF/PET/AI/PVF multi-layered laminated films at 100 to 450 microns in thickness. However, these constuctions can suffer from the drawback of poor adhesion of PVF to PET. Adhesion is typically augmented by treatment of the polymeric surfaces with corona discharge or a similar technology to increase adhesion of the PVF film. An adhesive can also be used on PVF to increase adhesion.

A polyvinylidene fluoride backsheet composition can be used to provide performance, and processing and cost improvements over current technology, as described in WO 08/157,159.

A concentrating photovoltaic module (CPV) is specially designed to focus solar radiation (typically by using concentrating lenses), requiring less silicon material in the module to achieve high light harvesting efficiency. CPV modules often require a mechanically more robust backsheet than the PVF/PET laminates typically used in other photovoltaic modules. Ideally, the backsheet material for such a module should be a rigid thermo-formable material that can provide better support for the module than less rigid multi-layer laminates.

Unfortunately PVF/PET laminated backsheet materials are not suitable for this type of application. Thus, there is a need for alternative backsheet constructions that are thermoformable and also provide good protective properties for the solar cells.

This invention provides an alternative thermoformable back sheet that provides good protective properties for solar cells. The thermoformable backsheet is composed of a methacrylic composition having a high Tg of greater than 110° C., optionally combined with a fluoropolymer outside layer, and can meet the weathering properties required in a photovoltaic backsheet. These properties include improved chemical resistance, dirt shedding, moisture resistance, and electrical insulation performance. Preferably, the fluoropolymer layer is a polyvinylidene fluoride polymer or copolymer.

The backsheet composition of the invention provides an excellent balance of cost and performance for photovoltaic modules, and especially for concentrating photovoltaic modules. The backsheet of the invention is thermally formable at elevated temperatures without visible defects.

### SUMMARY OF THE INVENTION

The invention relates to a photovoltaic module having a transparent glazing material, solar cells, and a thermoformable backsheet comprising a composition layer having a Tg of greater than 110° C., and optionally, a thin fluoropolymer layer on the outer side exposed to the environment.

### DETAILED DESCRIPTION OF THE INVENTION

The invention relates to a high Tg monolithic or multi-layer film or sheet useful as a thermoformable backsheet in a photovoltaic module. The multi-layer backsheet includes an inner high Tg composition, and an optional outer fluoropolymer layer (exposed to the environment) attached thereto.

By “photovoltaic modules”, as used herein is meant a construction of photovoltaic (PV) cell circuits sealed in an environmentally protective laminate. Photovoltaic modules may be combined to form photovoltaic panels that are pre-wired, field-installable units. A photovoltaic array is the complete power-generating unit, consisting of any number of PV modules and panels.

By “concentrating photovoltaic (CPV) modules” as used herein is meant a photovoltaic module designed to concentrate solar radiation at specific points within the CPV module, allowing for a reduction of silicon or other collecting material to only those areas onto which the radiation is focused.

By “thermoformable” or “thermal-formable” as used herein means the thermoplastic polymers are capable of being formed into a desirable shape by molding, injection molding, extrusion molding or other similar process, at a temperature above the softening temperature, and under external heat and force (pressure or vacuum). The thermoformable high Tg acrylic of the invention is a thermoplastic and not a thermoset. Thermosets, including epoxy resins, polytetrafluoroethylene (PTFE), and PVF are not thermoformable.

The high Tg composition is selected to provide better heat stability during formation of the PV module, and for improved performance over time. The high Tg composition is preferable a methacrylic-based polymer, polycarbonate, a blend of polycarbonate/methacrylate polymers, a blend of polycarbonate/polyester polymers, or a fiber-reinforced composite.

The high Tg methacrylic composition can be either a) a high Tg copolymer composed of methyl methacrylate and at least one other monomer, in which the resulting copolymer has a Tg greater than that of poly(methyl methacrylate) (PMMA, Tg of 105° C.), or b) a blend of an (meth)acrylic polymer and at least one miscible, semi-miscible, or compatible polymer, in which the overall Tg (for a miscible polymer) or at least one of the Tgs (for a semi-miscible polymer) is greater than 110° C. Examples of semi-miscible polymers with PMMA include, but are not limited to poly(styrene-maleic anhydride) (SMA), or polycarbonate (PC).

By “high Tg” as used herein means a Tg of 110° C. or greater, preferably 115° C. or greater, more preferably 120° C. or greater, and most preferably 125° C. or greater as measured by differential scanning calorimetry.

By “copolymer” as used herein means a polymer having two or more different monomer units. The copolymer could be a terpolymer with three or more different monomer units, or have four or more different monomer units. The copolymer may be a random copolymer, a gradient copolymer, or could be a block copolymer formed by a controlled polymerization process. The copolymer could also be a graft copolymer, or have a controlled structure such as a star or comb. Preferably, the copolymer is formed by a free radical polymerization process, and the process can be any polymerization method known in the art, including but not limited to emulsion, solution, suspension polymerization, and can be done in bulk, and semi-bulk. The methacrylic-based copolymer of the invention may be described herein as an “acrylic copolymer” a “methacrylic copolymer”, a “methylmethacrylate copolymer” and a “PMMA copolymer”.

The methyl methacrylate copolymer contains at least 50 weight percent of methyl methacrylate monomer units, preferably at least 75 weight percent and more preferably at least 85 weight percent methylmethacrylate monomer units. From 1 to 50, preferably 3 to 25, and more preferably 4 to 15 weight percent of at least one co-monomer is also included in the copolymer/blend. The Tg of the acrylic copolymer(s) or blend is at least 120° C., and preferably at least 125° C. Useful monomers that can impart a higher Tg to a copolymer include, but are not limited to, methacrylic acid, acrylic acid, itatonic acid, substituted styrenes, alpha methyl styrene, maleic anhydride, isobornyl methacrylate, norbornyl methacrylate, t-butyl methacrylate, cyclohexyl methacrylate, phenyl methacrylate, acrylamide, N-isopropyylacrylamide, methacrylamide, substituted maleimides, glutarimide, and maleimide. Several means known to those skilled in the art can be used to select useful monomers that can impart a higher Tg. One method is by considering candidate monomers by the Tg of their analogous homopolymer. Although other effects may also guide selection to those skilled in the art (e.g., polymer architecture, tacticity, inter- or intra-molecular synergistic interactions, etc.), homopolymer Tg's>105° C. typically indicate that the corresponding monomer of the homopolymer will increase the Tg of a copolymer relative to PMMA.

The methyl methacrylate copolymer may additionally contain one or more other vinyl monomers copolymerizable with methyl methacrylate, including but not limited to other acrylate and methacrylate monomers or other ethylenically unsaturated monomers, including but not limited to, styrene, alpha methyl styrene, and acrylonitrile. Other methacrylate and acrylate monomers useful in the monomer mixture include, but are not limited to, methyl acrylate, ethyl acrylate and ethyl methacrylate, butyl acrylate, iso-octyl methacrylate and acrylate, lauryl acrylate and lauryl methacrylate, stearyl acrylate and stearyl methacrylate, isobomyl acrylate and methacrylate, methoxy ethyl acrylate and methacrylate, 2-ethoxy ethyl acrylate and methacrylate, dimethylamino ethyl acrylate and methacrylate monomers.

In one embodiment, the methacrylic-based polymer is a copolymer containing at least 0.01 weight percent, and preferably from 1 to 25 weight percent, more preferably 2 to 20 weight percent of polar functionalized monomer units. The functionalization can result from the copolymerization of one or more functionalized monomers, the grafting of one or more functionalized monomers, or the post-polymerization functionalization of the acrylic polymer. The functionalization may exist as functionalized blocks in a block copolymer. Useful functionalized monomers include, but are not limited to those containing acid, anhydride, hydroxy, epoxy, and amine groups. Examples of useful functional cornonomers include, but are not limited to: amine functional: N,N-dimethylaminoethyl(meth)acrylate, N,N-diethylaminoethyl(meth)acrylate, (meth)acrylamide, N,N-dimethylacrylamide, N-methylolacrylamide, N-methylaminopropyl(meth)acrylamide, N,N-dimethylaminopropyl(meth)acrylamide, N-ethylamino propyl(meth)acrylamide, N,N-diethylaminopropyl (meth)acrylamide, N-methylacrylamide or N-t-butylacrylamide or N-ethyl (meth)acrylamide or chlorides of these compounds; hydroxyl functional: 2-hydroxyethyl(meth)acrylate, hydroxypropyl(meth)acrylate, 4-hydroxybutyl (meth)acrylate, glycidyl(meth)acrylate, ethyl alpha-hydroxymethacrylate, and 2,3-dihydroxypropyl(meth)acrylate; carboxylic acid and anhydride functionality: maleic anhydride, maleic acid, substituted maleic anhydride, mono-ester of maleic anhydride, itaconic anhydride, itaconic acid, substituted itaconic anhydride, glutaric anhydride, monoester of itaconic acid, fumaric acid, fumaric anhydride, fumaric acid, substituted fumaric anhydride, monoester of fumaric acid, crotonic acid and its derivatives, acrylic acid, and methacrylic acid; cyanoalkoxyalkyl (meth)acrylates such as omega-cyanoethoxyethyl acrylate, or omega-cyanoethoxyethyl methacrylate; vinyl monomers containing an aromatic ring and an hydroxyl group, such as vinylphenol, para-vinylbenzyl alcohol, meta-vinylphenethyl alcohol, vinyl pyrrolidone, and vinyl imidazole; and other functional monomers, allyl cellosolve, allyl carbinol, methylvinyl carbinol, allyl alcohol, methyllyl alcohol, glycidyl methacrylate, 3,4-epoxybutyl acrylate, acrylonitrile, methacrylonitrile, beta-cyanoethyl methacrylate, beta-cyanoethyl acrylate, and acrylate/methacrylates that incorporate trisalkoxy silane alkyl pendant groups, among others. Examples of polymerizable surfactants or macromonomers with hydrophilic moieties useful in the present invention include, but are not limited to sodium 1-allyloxy-2-hydroxypropane sulfonate, phosphate methacrylate monomer, polyethylene glycol) methylether methacrylate, 1-methacrylamido, 2-imidazolidinone ethane.

The thermoformable high Tg acrylic back sheet composition may also be a blend of a (meth)acrylic polymer or copolymer, and at least one polymer miscible/semi-miscible/compatible with the (meth)acrylic (co)polymer. For a miscible blend, the Tg of the total blend is at least 110° C. For a semi-miscible blend, at least one of the blend components has a high Tg of greater than 110° C. One or more of the blend components of the blend may have a Tg of less than 110° C. The blend preferably contains at least 50 weight percent of methylmethacrylate units total in the combined polymers. The blend preferably contains from 40 to 100 weight percent high Tg (meth)acrylic polymer. The blend preferably also contains from 1 to 60 weight percent of another high Tg polymer or copolymer (such as SMA).

The methacrylic composition layer may be produced as a sheet or film by known processes, such as extrusion, cell cast, injection molding, compression molding, blow molding, and continuous cast. The methacrylic composition layer has a thickness of from 0.5 mm to 5 mm, preferably from 1.0 to 3.0 mm, and more preferably from 1.5 to 2.5 mm.

The methacrylic composition sheet or film of the invention may contain one or more additives in an effective amount, including but not limited to impact UV stabilizers—which may be organic stabilizers or inorganic particles for permanent UV protection; plasticizers; fillers; coloring agents; pigments; antioxidants; antistatic agents; surfactants; toners; lubricants; and dispersing aids. The sheet or film may be clear or pigmented, in which case the preferred pigment is a white pigment.

The methacrylic composition layer is optionally covered on its outer surface by one or more fluoropolymer layers—primarily for weatherability, dirt-shedding, and good chemical resistance to toluene, chloroform, acetone, IPA, EtOH, and MeOH in spot tests. The outer fluoropolymer layer(s) may include, but is not limited to, polyvinylidene fluoride (PVDF), polytetrafluorethylene (PTFE), polyvinyl fluoride (PVF), and their copolymers or terpolymers.

The optional fluoropolymer layer has a total thickness of from 5 microns to 150 microns, preferably from 10 to 50 microns in thickness, and can be a single layer, or a multi-layer construction. The thickness of the layer is dependent on the method by which the layer is formed, with a layer formed from a coating having a dry thickness of from 5 to 50 microns, while laminated/coextruded layers are in the range of from 10 to 150 microns, and preferably 25 to 50 microns.

In one preferred embodiment, the optional fluoropolymer is PVDF. The PVDF layer(s) may be a homopolymer, a copolymer, a terpolymer or a blend of a PVDF homopolymer or copolymer with one or more other polymers that are compatible with the PVDF (co)polymer. PVDF copolymers and terpolymers of the invention are those in which vinylidene fluoride units comprise greater than 70 percent of the total weight of all the monomer units in the polymer, and more preferably, comprise greater than 75 percent of the total weight of the units. Copolymers, terpolymers and higher polymers of vinylidene fluoride may be made by reacting vinylidene fluoride with one or more monomers from the group consisting of vinyl fluoride, trifluoroethene, tetrafluoroethene, one or more of partly or fully fluorinated alpha-olefins such as 3,3,3-trifluoro-1-propene, tetrafluoropropene, 1,2,3,3,3-pentafluoropropene, 3,3,3,4,4-pentafluoro-1-butene, and hexafluoropropene, the partly fluorinated olefin hexafluoroisobutylene, perfluorinated vinyl ethers, such as perfluoromethyl vinyl ether, perfluoroethyl vinyl ether, perfluoro-n-propyl vinyl ether, and perfluoro-2-propoxypropyl vinyl ether, fluorinated dioxoles, such as perfluoro(1,3-dioxole) and perfluoro(2,2-dimethyl-1,3-dioxole), allylic, partly fluorinated allylic, or fluorinated allylic monomers, such as 2-hydroxyethyl allyl ether or 3-allyloxypropanediol, and ethene or propene. Preferred copolymers or terpolymers are formed with vinyl fluoride, trifluoroethene, tetrafluoroethene (TFE), and hexafluoropropene (HFP).

The PVDF layer could also be a blend of a PVDF polymer with a compatible polymer, such as polymethyl methacrylate (PMMA). PVDF and PMMA can be melt or solution blended to form a miscible/semi-miscible or compatible blend. A preferred embodiment is a blend of 10-80 weight percent of PVDF and 20-90 weight percent of polymethyl methacrylate copolymer. More preferably 50-70 PVDF and 30 to 50 weight percent of PMMA copolymer.

The PVDF layer could also consist of an acrylic-modified fluoropolymer (AMF), as described in U.S. Pat. No. 6,680,357, incorporated herein by reference.

The PVDF layer, in addition to PVDF may contain other additives, such as, but not limited to impact modifiers, UV stabilizers, plasticizers, fillers, coloring agents, pigments, antioxidants, antistatic agents, surfactants, toner, pigments, and dispersing aids. In a preferred embodiment, a pigment is added to aid in reflectance of light back into the solar module. Since UV resistance is a prime function of the back layer, UV adsorbers are preferably present at levels of from 0.05 percent to 5.0 percent in the PVDF and/or barrier layers. Also pigments can be employed at levels from 2.0 percent to 40 percent by volume, based on the polymer and pigment.

A backsheet having a high white reflection level helps to improve the light harvesting efficiency and reduce the heat build-up in the photovoltaic module. In one embodiment, 20-35 volume % of TiO₂ particles (based on the polymer and pigments) are dispersed in the PVDF layer to provide an excellent white reflective layer. In another embodiment, the white PVDF layer could be crosslinkable, such as by irradiation or thermal crosslinking after application. In another embodiment the PVDF is functionalized to improve adhesion to the methylmethacrylate layer. The functional fluoropolymer could be, for example, a maleic anhydride functional PVDF (such as KYNAR ADX from Arkema).

The fluorpolymer layer(s) may be applied to the methacrylic composition by any known means, such as, but not limited to, coating, by lamination, with an adhesive or tie-layer, or by coextrusion. The backsheet is preferably formed in a coextrusion or blown film process, then applied to the back of the photovoltaic module—but extrusion lamination is also possible.

In one embodiment, the PVDF layer directly adheres to the methacrylic composition without the need of a tie layer or adhesive. Useful PVDF copolymers for direct adhesion include PVDF copolymers with HFP levels of from 5-30 weight percent, and maleic anhydride grafted PVDF. The adhesion takes place either by a coextrusion of the multi-layer back sheet prior to assembly into the photovoltaic module, or else forming a laminate of separate layers during the heat/cure process for forming the module as a whole. The PVDF layer has a thickness of 25-50 um.

Another approach to forming a polyvinylidene fluoride outer layer is by coating with a solvent or aqueous-based coating. An aqueous-based polyvinylidene fluoride can be applied via a latex coating as an acrylic modified fluoropolymer. A fluoropolymer layer as a solvent coating based on PVDF or PVDF copolymers may be applied by known means, such as spray coating, flow coating, dip coating, screen coating, brush coating, and laser jet print coating.

In one embodiment, a fluoropolymer/acrylic (at a ratio of 90/10 to 0/100) white reflective layer is laminated/coated over a clear or white PMMA back protection sheets during an on-line extrusion or co-extrusion processes. In one embodiment, KYNAR AQUATEC® fluoropolymer/acrylic coatings are applied to high Tg PLEXIGLAS PMMA sheets with the dry coating thickness of 5-25 um and dried from ambient temperature to 90° C. The PVDF coating may have a pigment volume content, using pigments such as TiO₂ or BaSO₄ 0% to 40%, and preferably from 0.01 to 30% by weight based on the total polymer solid content.

The photovoltaic module consists of a front glazing material, a middle layer of solar cells, and the back sheet.

The glazing material may be glass or plastic, and may optionally be coated with a thin layer of a fluoropolymer. A concentrating photovoltaic module will include lenses to concentrate solar radiation onto smaller areas of solar collectors. In one embodiment, the front glazing material may also be a high Tg methyl methacrylate copolymer, which may be the same or different from that used in the backsheet. The glazing needs to allow transmission of solar radiation in at least some usable part of the spectrum. The glazing may be clear or hazy, and may have a smooth or matte surface.

The interior solar collectors of the photovoltaic module consists of a material that is capable of converting solar radiation into electrical current. The interior layer can be composed of materials known in the art for this purpose including, but not limited to amorphous silicon, copper indium selenide (CIS), copper-indium gallium selenide (CIGS), quantum dots, cadmium telluride (CdTe), amorphous silicon/microcrystalline silicon blend.

The solar radiation collectors are generally fragile, and so are encapsulated for protection. The encapsulant can be any encapsulant known in the art. In one embodiment the encapsulant is poly(ethylene vinyl acetate), poly(ethylene-acrylic acid ionomer, silicone, polyvinyl butyral (PVB) with peroxides and stabilizers, or thermoplastic EVA alloys with functional polyolefins.

The thermoformable high Tg methacrylic composition sheets, that are optionally fluoropolymer coated, are useful as the back sheet in a photovoltaic module, and especially in concentrating photovoltaic modules. A backsheet of 1.0-2.0 mm can meet the requirements of 20-year outdoor weathering performance, excellent thermal dimensional stability (85° C./85% RH), excellent moisture resistance (<2.5 g/m² day), and excellent electrical insulation (dielectric breakdown>14KV) for use as a back sheet in concentrating photovoltaic modules. For methacrylic composition sheets alone, the dielectric breakdown is larger than 20 KV/mm, indicating that the dielectric breakdown of the methacrylic composition sheets will be larger than 14KV when the methacrylic composition thickness reaches >0.7 mm. The backsheet meets a damp heat test at 85° C./85% RH for 1000 hrs and a thermal cycle test at −40° C. to 90° C. for 200 cycles, by showing no delamination. No delamination between a PVDF copolymer layer and a methacrylic composition sheet should occur during thermal forming processes and environmental tests.

The backsheet of the invention is thermal formable under external pressure (or vacuum) at elevated temperature (at a temperature higher than the Tg and close to the Tg of the fluoropolymer). The sheet can be thermoformed under vacuum to a depth of 2″ without visible cracks or defects. A preferred fluoropolymer layer is a polyvinylidene fluoride/hexafluoropropene copolymer.

In some applications it is desirable for the backsheet to have a high reflectance, in which case the backsheet is pigmented. In other applications, a transparent backsheet is desired.

### EXAMPLES

Unless otherwise noted, all percentages are weight percentages, and all molecular weights are weight average molecular weights.

The forming mold possessed the depth up to 2 inches, made of aluminum alloys while the thermal forming was processed under a vacuum. The heating system was controlled based on IR thermal heating. The thermal forming temperature was determined by a heat sensitive label.

Optical transmission was measured using a Perkin Elmer Lambda 850/800 UV/Vis with an integrating sphere in a transmission mode while the optical reflectance was measured in a reflection mode. The haze was measured at a BYK

Gardner Haze meter in the photopic region. The Kynar®, Plexiglas®, and Altuglas®, trademarks are owned by Arkema Inc. and Arkema France, and the products bearing these marks are available from Arkema Inc and Arkema France.

### Example 1

A KYNAR FLEX 2850 polyvinylidene fluoride copolymer film (50 um) was directly laminated over 2.0 mm clear PLEXIGLAS acrylic sheets containing PLEXIGLAS V045/ALTUGLAS HT 121 (60/40) with a Tg of 113° C. during the melt extrusion of the pMMA sheets at 470° F. ALTUGLAS HT 121 is a copolymer of methyl methacrylate and methacrylic acid. The average haze levels of the clear laminated back sheets were controlled around 4.5%, with T=92.9% at 560 nm. The laminated sheets were thermally formed under external pressure (in a vacuum) when the sheets were heated at 320-330° F. KYNAR FLEX 2850 film laminated PMMA back sheets passed the crosshatch peel-off adhesion tests with no delamination as ranked at 5B (100%). The KYNAR FLEX 2850 film laminated side exhibited good stain resistance and excellent chemical resistance to toluene, chloroform, IPA, EtOH, MeOH, and 70% IPA based rubbing alcohol in spot tests.

### Example 2

A KYNAR FLEX 2850 fluorocopolymer film (50 um) was directly laminated over 2.0 mm clear PLEXIGLAS acrylic sheets containing PLEXIGLAS V045/ALTUGLAS HT 121 (70/30) with a Tg of 111° C. during the melt extrusion of the pMMA sheets at 470° F. The average haze levels of the laminated PMMA back sheets were controlled around 4.2%, with T=92.9% at 560 um. The laminated sheets were thermally formed in a vacuum when the sheets were heated at 320-330° F. KYNAR FLEX 2850 film laminated PMMA sheets passed the crosshatch peel-off adhesion tests with no delamination as ranked at 5B (100%). The KYNAR FLEX 2850 film laminated side exhibited good stain resistance and excellent chemical resistance to toluene, chloroform, IPA, EtOH, MeOH, and 70% IPA based rubbing alcohol in spot tests.

### Example 3

A KYNAR FLEX 2500 polyvinylidene fluoride copolymer film (35 um) was directly laminated over 1.5 mm clear PLEXIGLAS acrylic sheet sheets containing PLEXIGLAS V045/ALTUGLAS HT 121 (70/30) with a Tg of 111° C. during the melt extrusion of the pMMA sheets at 460° F. The average haze levels of the laminated back sheets were controlled around 3.8%, with T=93.0% at 560 nm. The laminated sheets were thermally formed in a vacuum when the sheets were heated at 320-330° F. KYNAR FLEX 2500 film laminated PMMA sheets passed the crosshatch peel-off adhesion tests with no delamination as ranked at 5B (100%). The KYNAR FLEX 2500 film laminated side exhibited improved stain resistance and excellent chemical resistance to chloroform, IPA, EtOH, MeOH, and 70% IPA based rubbing alcohol in spot tests.

### Example 4

A KYNAR FLEX 2500 fluoropolymer film (35 um) was directly laminated over 2.0 mm clear PLEXIGLAS acrylic sheets containing PLEXIGLAS V045/PLEXIGLAS HT 121 (70/30) with a Tg of 110° C. during the melt extrusion of the pMMA sheets at 460° F. The average haze levels of the laminated back sheets were controlled around 3.9%, with T=93.0% at 560 nm. The laminated sheets were thermally formed under external pressure (in a vacuum) when the sheets were heated at 320-330° F. KYNAR FLEX 2500 film laminated PMMA sheets passed the crosshatch peel-off adhesion tests with no delamination as ranked at 5B (100%). The KYNAR FLEX 2500 film laminated side exhibited excellent chemical resistance to chloroform, IPA, EtOH, MeOH, and 70% IPA based rubbing alcohol in spot tests.

### Example 5

1.50 mm PLEXIGLAS V045/PLEXIGLAS HT 121 (70/30) based PMMA sheets at the width of 11 inches were extruded at a temperature of 470° F. The back sheets were thermally formed in a vacuum when the sheets were heated at 320-330° F. After the vacuum forming, the clear KYNAR AQUATEC PVDF-HFP/acrylic (70/30) layer was coated as an exterior layer through a spray coating. This fluoropolymer/acrylic coating was dried at 80° C. for 30 minutes. KYNAR AQUATEC coated PMMA sheets passed the crosshatch peel-off adhesion tests with no delamination as ranked at 5B (100%). The optical transmission on KYNAR AQUATEC coated PMMA side was measured at 93.4% at 560 nm.

### Example 6

1.50 mm PLEXIGLAS V045/ALTUGLAS HT 121 (70/30) based PMMA sheets at the width of 11 inches were extruded at the temperature of 470° F. The back sheets were thermally formed in a vacuum when the sheets were heated at 320-330° F. After the vacuum forming, the white KYNAR AQUATEC PVDF-HFP/acrylic (70130) layer containing 20 vol. % TiO₂ (R960 rutile from DuPont) was coated as an exterior layer through a spray coating. This fluoropolymer/acrylic coating was dried at 80° C. for 30 minutes. KYNAR AQUATEC coated PMMA sheets passed the crosshatch peel-off adhesion tests with no delamination as ranked at 5B (100%). The optical reflection on white KYNAR AQUATEC coated PMMA side was measured over 90% at 560 nm. The solar reflectance of 71% was measured in th efull solar spectrum from 300 nm to 2500 nm.

### Example 7

2.5 mm PLEXIGLAS HT 121 based PMMA sheets at a width of 27 inches were extruded at the temperature of 480° F. 2.5 mm PLEXIGLAS HT 121 based optical sheets (with the Tg of 123° C., optical transmission of 92.5% and haze of <1%) passed the required enviromental tests such as a damp test at 85° C./85% RH for 1000 hrs and a thermal cycle test at −40° C. to 90° C. for 200 cycles as well as humidity freeze tests. 2.5 mm PLEXIGLAS HT 121 based PMMA sheets were thermally formed under the external pressure (in a vacuum) when the sheets were heated at 330-340° F. After the vacuum forming, the depth of formed PLEXIGLAS HT 121 sheet parts was at 1 inch without visible cracks/defects.

### Example 8

2.5 mm PLEXIGLAS HT 121 based PMMA sheets at a width of 27 inches were extruded at the temperature of 480° F. The optical sheets possessed very low thermal shrinkage of −0.5%/−0.4% at 120° C. for 120 minutes along both of MD and TD directions. The linear CTE (coefficient of thermal expansion) was measured at about 40 ppm/° C. from 25 to 100° C. The back sheets were thermally formed in a vacuum when the sheets were heated at 330-340° F. After the vacuum forming, the clear KYNAR AQUATEC PVDF-HFPlacrylic layer (70/30) was coated as an exterior layer through a spray coating. This fluoropolymer/acrylic coating was dried at 80° C. for 30 minutes. KYNAR AQUATEC coated PMMA sheets passed the crosshatch peel-off adhesion tests with no delamination as ranked at 5B (100%). The optical transmission on KYNAR AQUATEC coated PMMA side was measured at 93.4% at 560 nm.

### Example 9

2.5 mm PLEXIGLAS HT 121 based PMMA sheets at a width of 27 inches were extruded at the temperature of 480° F. The back sheets were thermally formed in a vacuum when the sheets were heated at 330-340° F. After the vacuum forming, the KYNAR AQUATEC PVDF-HFP/acrylic layer (70/30) containing 20 vol. % TiO2 (R960 rutile) was coated as an exterior layer through a spray coating. This fluoropolymer/acrylic coating was dried at 80° C. for 30 minutes. KYNAR AQUATEC coated PMMA sheets passed the crosshatch peel-off adhesion tests with no delamination as ranked at 5B (100%). The optical reflection on white KYNAR AQUATEC coated PMMA side was measured up to 90% at 560 nm. The solar reflectance of 73% was measured in the full solar spectrum from 300 nm to 2500 nm.

### Example 10

2.0 mm PLEXIGLAS HT 121 based PMMA sheets at a width of 27 inches were extruded at the temperature of 480° F. 2.0 mm PLEXIGLAS HT 121 based optical sheets with the optical transission of 92.5% and haze of <1% passed the environmental tests such as a damp test at 85° C./85% RH for 1000 hrs and a thermal cycle test at −40° C. to 90° C. for 200 cycles as well as humidity freeze tests. 2.0 mm PLEXIGLAS HT 121 based PMMA sheets were thermally formed under the external pressure (in a vacuum) when the sheets were heated at 320-340° F. After the vacuum forming, the depth of formed PLEXIGLAS HT 121 sheet parts was at 1 inch without visible cracks/defects.

### Example 11

2.0 mm PLEXIGLAS HT 121 based PMMA sheets at a width of 27 inches were extruded at the temperature of 480° F. 2.0 mm PLEXIGLAS HT 121 based PMMA sheets were thermally formed under the external pressure (in a vacuum) when the sheets were heated at 320-340° F. After the vacuum forming, the water-borne KYNAR AQUATEC fluorocopolymer/acrylic (70/30) layer was coated as an exterior layer by a spray coating and dried at ambient temperature. No delamination between the AQUATEC copolymer layer and the PMMA sheet substrate should occur. This can significantly improve the stain resistance and weathering performance in PV modules. The optical transmission on KYNAR AQUATEC coated PMMA side was measured at 93.4% at 560 nm.

### Example 12

2.0 mm PLEXIGLAS HT 121 based PMMA sheets at a width of 27 inches were extruded at the temperature of 480° F. 2.0 mm PLEXIGLAS HT 121 based PMMA sheets were thermally formed under the external pressure (in a vacuum) when the sheets were heated at 320-340° F. After the vacuum forming, the water-borne KYNAR AQUATEC fluorocopolymer/acrylic (70/30) layer containing 18 vol. % TiO2 (R960 rutile) was coated as an exterior layer by a spray coating and dried at 80° C. for 30 minutes. The optical reflection on white KYNAR AQUATEC coated PMMA side was measured over 92% at 560 nm. No delamination between the AQUATEC copolymer layer and the PMMA sheet substrate should occur. The solar reflectance of 73% was measured in the full solar spectrum from 300 nm to 2500 nm. This can significantly improve the light harvesting efficiency and reduce the heat build-up in PV modules.

### Example 13

2.0 mm PLEXIGLAS HT 121 based PMMA sheets at a width of 27 inches were extruded at the temperature of 480° F. 2.0 mm PLEXIGLAS HT 121 based PMMA sheets were thermally formed under the external pressure (in a vacuum) when the sheets were heated at 320-340° F. After the vacuum forming, the water-borne KYNAR AQUATEC fluorocopolymer/acrylic (70/30) layer containing 18 vol. % TiO2 (R960 rutile) and 12 vol. % BaSO4 (from Cimbar XF) was coated as an exterior layer by a spray coating and dried at 80° C. for 30 minutes. The optical reflection on white KYNAR AQUATEC coated PMMA side was measured over 92% at 560 nm. No delamination between the AQUATEC copolymer layer and the PMMA sheet substrate should occur. The solar reflectance of 74% was measured in the full solar spectrun from 300 nm to 2500 nm.

### Example 14

2.0 mm PLEXIGLAS HT 121 based PMMA sheets at a width of 27 inches were extruded at the temperature of 480° F. 2.0 mm PLEXIGLAS HT 121 based PMMA sheets were thermally formed under the external pressure (in a vacuum) when the sheets were heated at 320-340° F. After the vacuum forming, the water-borne KYNAR AQUATEC fluorocopolymer/acrylic (70/30) layer containing 30 vol. % TiO2 (R960 rutile) and 1% 3-Gylcidoxypropyl-trimethoxysilane (˜97%, a crosslinking agent from Alfa Aesar) was coated as an exterior layer by a spray coating and dried at 80° C. for 30 minutes. The optical reflection on white KYNAR AQUATEC coated PMMA side was measured over 92% at 560 nm. No delamination between the AQUATEC copolymer layer and the PMMA sheet substrate should occur. The solar reflectance of 77% was measured in the full solar spectrun from 300 nm to 2500 nm.

What is claimed is:

1. A photovoltaic module comprising, in order from front to back:
a) a transparent glazing material;
b) solar cells
c) a thermoformable backsheet comprising a thermoplastic composition layer having a Tg of greater than 110° C., and optionally a thin fluoropolymer layer on the outer side exposed to the environment.

2. The photovoltaic module of claim 1, wherein said thermoformable backsheet composition is selected from the group consisting of a methacrylic-based polymer, polycarbonate, a blend of polycarbonate/methacrylate polymers, a blend of polycarbonate/polyester polymers, and a fiber-reinforced composite.

3. The photovoltaic module of claim 1, wherein said thermoformable backsheet composition comprises a methacrylic-based polymer.

4. The photovoltaic module of claim 1, wherein said photovoltaic module is a concentrating photovoltaic module or a thin film photovoltaic module.

5. The photovoltaic module of claim 4, comprising an acrylic concentrating lens.

6. The photovoltaic module of claim 1, wherein said thermoformable backsheet is white.

7. The photovoltaic module of claim 1, wherein said thermoformable backsheet is transparent.

8. The photovoltaic module of claim 1, wherein said thermoformable backsheet composition has a Tg of 115° C. or greater.

9. The photovoltaic module of claim 8, wherein said backsheet composition has a Tg of 120° C. or greater.

10. The photovoltaic module of claim 9, wherein said backsheet composition has a Tg of 125° C. or greater.

11. The photovoltaic module of claim 3, wherein said methacrylic-based composition is a copolymer comprising at least 50 percent by weight of methyl methacrylate units, and from 3 to 25 weight percent of one or more monomer units selected from the group consisting of methacrylic acid, acrylic acid, itatonic acid, substituted styrenes, alpha methyl styrene, maleic anhydride, isobornyl methacrylate, norbornyl methacrylate, t-butyl methacrylate, cyclohexyl methacrylate, phenyl methacrylate, maleimide, substituted maleimides, glutarimide, methacrylamide, N-isopropylacrylamide, and acrylamide.

12. The photovoltaic module of claim 1, wherein said thermoformable backsheet composition comprises a blend of a methacrylic polymer or copolymer and a polymer that is miscible/semi-miscible/compatible with said methacrylic polymer or copolymer, wherein at least one of the blend polymers has a Tg of greater than 110° C.

13. The photovoltaic module of claim 1 wherein said thermoformable backsheet composition layer has a thickness of from 0.5 to 5 mm.

14. The photovoltaic module of claim 1 wherein said thermoformable backsheet composition layer has a thickness of from 1.5 to 2.5 mm.

15. The photovoltaic module of claim 1, wherein said fluoropolymer layer is from 5 to 150 microns thick.

16. The photovoltaic module of claim 15, wherein said fluoropolymer layer is from 10 to 50 microns thick.

17. The photovoltaic module of claim 1, wherein said fluoropolymer layer comprises at least 50 weight percent of vinylidene fluoride units.

18. The photovoltaic module of claim 17, wherein said fluoropolymer comprises from 75 to 95 weight percent of vinylidene fluoride units and from 5 to 40 weight percent of hexafluoropropylene units.

19. The photovoltaic module of claim 1, wherein said fluoropolymer is an acrylic modified fluoropolymer.

20. The photovoltaic module of claim 1, wherein said fluoropolymer layer or thermoplastic composition layer contains from 0 to 40 volume percent of titanium dioxide or BaSO₄ particles, based on the volume of pigments and fluoropolymer.

21. The photovoltaic module of claim 1, wherein said fluoropolymer layer is crosslinkable.

22. The photovoltaic module of claim 1, wherein said thermoplastic composition layer is crosslinkable, and reactive with multi-functional groups.
